(19) United States
(12) Patent Application Publication
(10) Pub. No.: US 2024/0096593 A1
(43) Pub. Date: Mar. 21, 2024

(54) PLASMA PROCESSING DEVICE, PLASMA PROCESSING METHOD, AND SEMICONDUCTOR DEVICE MANUFACTURING METHOD

(71) Applicant: Kioxia Corporation, Tokyo (JP)

(72) Inventor: Toshiyuki SASAKI, Yokkaichi Mie (JP)

(73) Assignee: Kioxia Corporation, Tokyo (JP)

(21) Appl. No.: 18/450,625

(22) Filed: Aug. 16, 2023

(30) Foreign Application Priority Data
Sep. 16, 2022 (JP) 2022-147666

(51) Int. Cl. H01J 37/32; H01L 21/311

(52) U.S. Cl. CPC H01J 37/32009; H01J 37/32449; H01J 37/3299; H01L 21/31116; H01J 2237/327; H01J 2237/334

(57) ABSTRACT

A plasma processing device includes a chamber, a plurality of direct current power supplies, and a controller. The direct current power supplies are provided in an upper portion and on a side wall of the chamber, wherein the direct current power supplies are configured to operate individually. The controller is configured to control the direct current power supplies such that the direct current power supplies apply respective direct current voltages independent of each other.

### CROSS-REFERENCE TO RELATED APPLICATION(S)

This application is based upon and claims the benefit of priority from Japanese Patent Application No. 2022-147666, filed Sep. 16, 2022, the entire contents of which are incorporated herein by reference.

### FIELD

Embodiments described herein relate generally to a plasma processing device, a plasma processing method, and a semiconductor device manufacturing method.

### BACKGROUND

In some cases, depending on a kind or the like of a gas used in a plasma processing, a film is liable to be deposited in a chamber, or a deposited film is difficult to remove. In such cases, time needed for cleaning in the chamber increases.

### DESCRIPTION OF THE DRAWINGS

FIG. 1 is a sectional view showing an example of a structure of a plasma processing device according to a first embodiment.

FIG. 2 is a sectional view showing an example of a configuration of a direct current power supply according to the first embodiment.

FIG. 3 is a plan view showing an example of a configuration of an upper direct current power supply according to the first embodiment.

FIG. 4 is a timing chart showing an example of an operation of the plasma processing device according to the first embodiment.

FIG. 5 is a sectional view showing an example of a structure of a semiconductor device according to a second embodiment.

FIG. 6A is a sectional view showing an example of a method of manufacturing the semiconductor device according to the second embodiment.

FIG. 6B is a sectional view showing an example of a method of manufacturing the semiconductor device according to the second embodiment.

FIG. 7A is a sectional view showing an example of a method of manufacturing the semiconductor device according to the second embodiment.

FIG. 7B is a sectional view showing an example of a method of manufacturing the semiconductor device according to the second embodiment.

FIG. 8A is a sectional view showing an example of a method of manufacturing the semiconductor device according to the second embodiment.

FIG. 8B is a sectional view showing an example of a method of manufacturing the semiconductor device according to the second embodiment.

FIG. 9A is a sectional view showing an example of a method of manufacturing the semiconductor device according to the second embodiment.

FIG. 9B is a sectional view showing an example of a method of manufacturing the semiconductor device according to the second embodiment.

FIG. 10A is a sectional view showing an example of a method of manufacturing the semiconductor device according to the second embodiment.

FIG. 10B is a sectional view showing an example of a method of manufacturing the semiconductor device according to the second embodiment.

### DETAILED DESCRIPTION

Embodiments provide a plasma processing device, a plasma processing method, and a semiconductor device manufacturing method such that a cleaning time can be shortened.

In general, according to one embodiment, a plasma processing device includes a chamber, a plurality of direct current power supplies, and a controller. The direct current power supplies are provided in an upper portion and on a side wall of the chamber, wherein the direct current power supplies are configured to operate individually. The controller is configured to control the direct current power supplies such that the direct current power supplies apply respective direct current voltages independent of each other.

Hereafter, embodiments according to the present disclosure will be described, with reference to the drawings. The embodiments do not limit the disclosure. The drawings are schematic or conceptual, and a proportion and the like of each portion is not necessarily the same as that of the actual portion. In the specification and the drawings, an identical reference sign is allotted to an element the same as an element previously described in relation to a previously described drawing, and a detailed description thereof is omitted as appropriate.

### First Embodiment

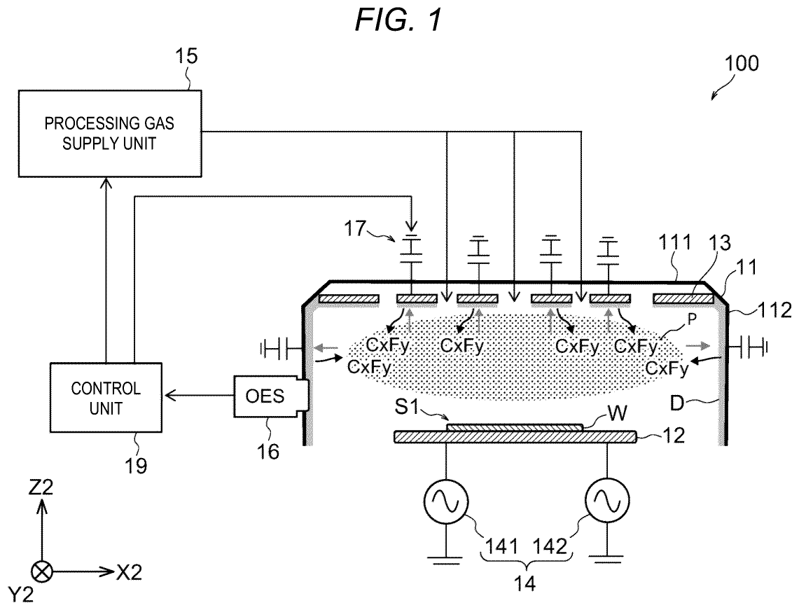

FIG. 1 is a sectional view showing an example of a structure of a plasma processing device 100 according to a first embodiment. The plasma processing device of FIG. 1 is, for example, a processing device (semiconductor manufacturing device) such as a plasma etching device.

The plasma processing device of FIG. 1 includes a processing chamber 11, a mounting table (stage) 12, an upper electrode 13, an alternating current power supply 14, a processing gas supply unit (or processing gas supplier) 15, a sensor 16, a direct current power supply 17, and a control unit (or controller) 19. The stage 12, the upper electrode 13, and the alternating current power supply 14 are an example of a gas processing unit (or gas processor).

The processing chamber 11 houses a wafer W that is a processing target. FIG. 1 shows an X2 direction and a Y2 direction, which are parallel to a front face S1 and a back face of the wafer W and perpendicular to each other, and a Z2 direction, which is perpendicular to the front face S1 and the back face of the wafer W. In the present specification, a +Z2 direction is treated as an upward direction, and a −Z2 direction is treated as a downward direction. The −Z2 direction of the present embodiment may coincide with a direction of gravity, but need not coincide with the direction of gravity.

The wafer W in the processing chamber 11 is mounted on the stage 12. The stage 12 also functions as a lower electrode for plasma processing.

The upper electrode 13 is provided above the stage 12. The upper electrode 13 is provided, for example, in an upper portion of the processing chamber 11, in a position separated from a top plate 111. The plasma processing device 100 causes plasma to be generated between the upper electrode 13 and the stage 12, supplies the plasma to the front face S1 of the wafer W, and processes the wafer W using the plasma. Specifically, the front face S1 of the wafer W is etched using a dry etching in which plasma is used. In the embodiments, for example, a hole is formed using a dry etching in a processing target film formed on the front face S1 of the wafer W.

The alternating current power supply 14 supplies an alternating current voltage to the stage 12. Because of this, a plasma P is generated between the upper electrode 13 and the stage 12. The alternating current power supply 14 has an alternating current power supply 141 and an alternating current power supply 142. The alternating current power supply 141 is a high frequency power supply having a frequency of, for example, 60 MHz. The alternating current power supply 142 is a high frequency power supply having a frequency of, for example, 400 kHz.

The processing gas supply unit 15 supplies a plasma generating processing gas into the processing chamber 11. The processing gas, for example, passes through a multiple of through holes provided in the upper electrode 13. The upper electrode 13 and the stage 12 generate plasma from the processing gas using the alternating current voltage from the alternating current power supply 14. The processing gas includes, for example, a fluorocarbon gas. The processing gas includes, for example, hydrogen (H₂).

The sensor 16 detects an amount of radicals used in a plasma processing in the processing chamber 11, that is, in the plasma P. The sensor 16 is a device that analyzes using, for example, emission spectrometry. The sensor 16 is, for example, an optical emission spectrometry (OES) device. The sensor 16 measures a light emission intensity of products (radicals) in the processing chamber 11 during a plasma etching (that is, while plasma is being generated). The light emission intensity is calculated from, for example, an emission wavelength of each product. For example, when a gas including C₂F₄ is used as an etching gas, CF₂ radicals and C₂ radicals are generated in the processing chamber 11. The sensor 16 measures each light emission intensity from the emission wavelengths of the CF₂ radicals and the C₂ radicals, thereby measuring the amount generated of each radical.

A multiple of the direct current power supplies 17 are provided, and can be controlled individually. The direct current power supply 17 is provided, for example, outside the processing chamber 11. The multiple of direct current power supplies 17 apply a direct current voltage to the upper portion and a side wall 112 of the processing chamber 11. The direct current voltage is, for example, a negative voltage. The direct current power supply 17 that applies a direct current voltage to the upper portion of the processing chamber 11 is, for example, electrically connected to the upper electrode 13. Power applied by the direct current power supply 17 is, for example, approximately 200 W to approximately 1,000 W. Because of this, a deposited film D deposited in the processing chamber 11 during a plasma processing of the wafer W can be etched during a plasma processing of the wafer W. The deposited film D is, for example, a film formed by plasma processing reaction products accumulating on the upper electrode 13 and the side wall 112. The deposited film D is, for example, a fluorocarbon-based deposited film. In this case, fluorocarbon-based (CₓF_{y}) radicals generated by etching the deposited film D can be supplied to the wafer W. As a result of this, radicals generated from the deposited film D can be utilized in the plasma processing of the wafer W, while partially removing the deposited film D.

The control unit 19 controls an operation of the plasma processing device 100. The control unit 19 controls an operation of the processing chamber 11, an operation of the stage 12, a turning on and off and a current of the alternating current power supply 14, a turning on and off of, and a flow rate of processing gas supplied by, the processing gas supply unit 15, and the like.

More specifically, the control unit 19 controls the multiple of direct current power supplies 17 in such a way that the direct current power supplies 17 apply a direct current voltage independently of each other. Because of this, the deposited film D in the processing chamber 11 can be partially removed, and a cleaning time can be shortened. More specifically, the control unit 19 controls the multiple of direct current power supplies 17 in such a way that the direct current power supplies 17 apply a direct current voltage independently of each other during a plasma processing (during an etching of a processing target film of the wafer W). Because of this, the deposited film D in the processing chamber 11 can be partially removed during a plasma processing.

Also, a further cleaning of the processing chamber 11 may be carried out after a plasma processing of the wafer W is completed. Cleaning after a plasma processing of the wafer W is such that, for example, a cleaning gas including oxygen (O_{y}) is supplied into the processing chamber 11. At this time, the control unit 19 controls the multiple of direct current power supplies 17 in such a way that the direct current power supplies 17 apply a direct current voltage during the cleaning.

Also, the control unit 19 controls the multiple of direct current power supplies 17 in such a way that the direct current power supplies 17 apply a direct current voltage independently of each other in accordance with a result of a detection by the sensor 16. More specifically, the control unit 19 calculates a spatial distribution of radicals to be used in a plasma processing in the processing chamber 11 based on a result of a detection by the sensor 16, and controls the multiple of direct current power supplies 17 in such a way that the direct current power supplies 17 apply a direct current voltage independently of each other in accordance with the calculated spatial distribution. The control unit 19 calculates the spatial distribution using, for example, the Abel transform.

Also, the control unit 19 supplies the processing gas supply unit 15. More specifically, the control unit 19 controls the processing gas supply unit 15 in accordance with a timing of an application of direct current voltage by the multiple of direct current power supplies 17.

Next, details of the direct current power supply 17 will be described.

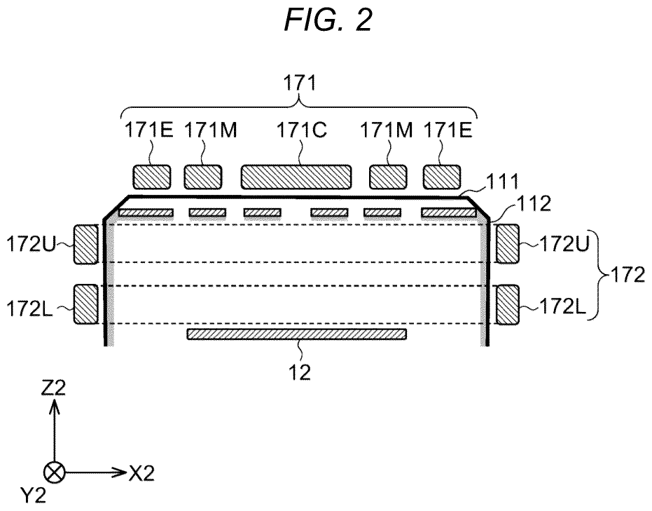

FIG. 2 is a sectional view showing an example of a configuration of the direct current power supply 17 according to the first embodiment.

The multiple of direct current power supplies 17 have one or more upper direct current power supplies 171 and one or more side wall direct current power supplies 172.

The upper direct current power supply 171 is provided on the upper electrode 13 side, that is, on the top plate (upper portion) 111 of the processing chamber 11. The one or more upper direct current power supplies 171 are provided disposed in differing positions on the top plate 111 of the processing chamber 11, and can be controlled individually. The one or more upper direct current power supplies 171 apply direct current voltage to the upper portion of the processing chamber 11. In the example shown in FIG. 2, the multiple of upper direct current power supplies 171 have three upper direct current power supplies, those being 171C, 171M, and 171E.

The side wall direct current power supply 172 is provided on the side wall 112 of the processing chamber 11. One or more side wall direct current power supplies 172 are provided in differing positions on the side wall 112 of the processing chamber 11, and can be controlled individually. The one or more side wall direct current power supplies 172 apply a direct current voltage to an electrode (not shown) provided on the side wall 112 of the processing chamber 11. In the example shown in FIG. 2, the multiple of side wall direct current power supplies 172 have two side wall direct current power supplies, those being 172U and 172L.

When seen from the Z2 direction, the side wall direct current power supply 172 is provided following the side wall 112 of the processing chamber 11. The side wall direct current power supply 172U is provided in, for example, an upper portion of the side wall 112. The side wall direct current power supply 172L is provided in, for example, a lower portion of the side wall 112.

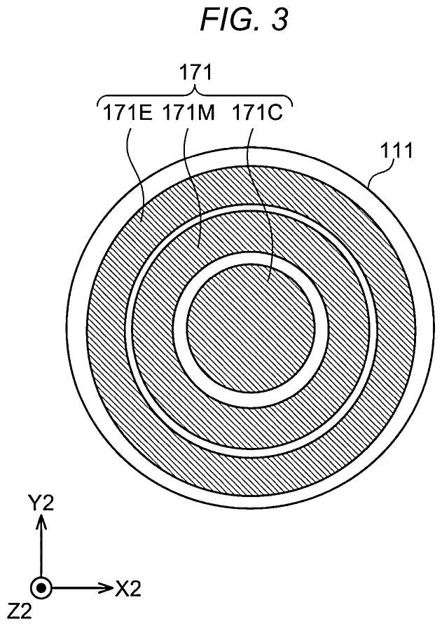

FIG. 3 is a plan view showing an example of a configuration of the upper direct current power supply 171 according to the first embodiment. FIG. 3 is a drawing wherein the upper direct current power supply 171 shown in FIG. 2 is seen from the Z2 direction.

The upper direct current power supply 171C is provided in a central portion of the top plate 111. In the example shown in FIG. 3, a form of the upper direct current power supply 171C is approximately circular.

The upper direct current power supply 171E is provided in an outer peripheral end portion of the top plate 111. In the example shown in FIG. 3, a form of the upper direct current power supply 171E is approximately annular.

The upper direct current power supply 171M is provided between the upper direct current power supply 171C and the upper direct current power supply 171E. In the example shown in FIG. 3, a form of the upper direct current power supply 171M is approximately annular.

As shown in FIGS. 2 and 3, the multiple of upper direct current power supplies 171C, 171M, and 171E and the multiple of side wall direct current power supplies 172U and 172L are provided separated into individual elements. Because of this, a direct current voltage can be applied independently in the position of each of the multiple of upper direct current power supplies 171C, 171M, and 171E and the multiple of side wall direct current power supplies 172U and 172L.

Next, a plasma processing method in which the plasma processing device 100 is used will be described.

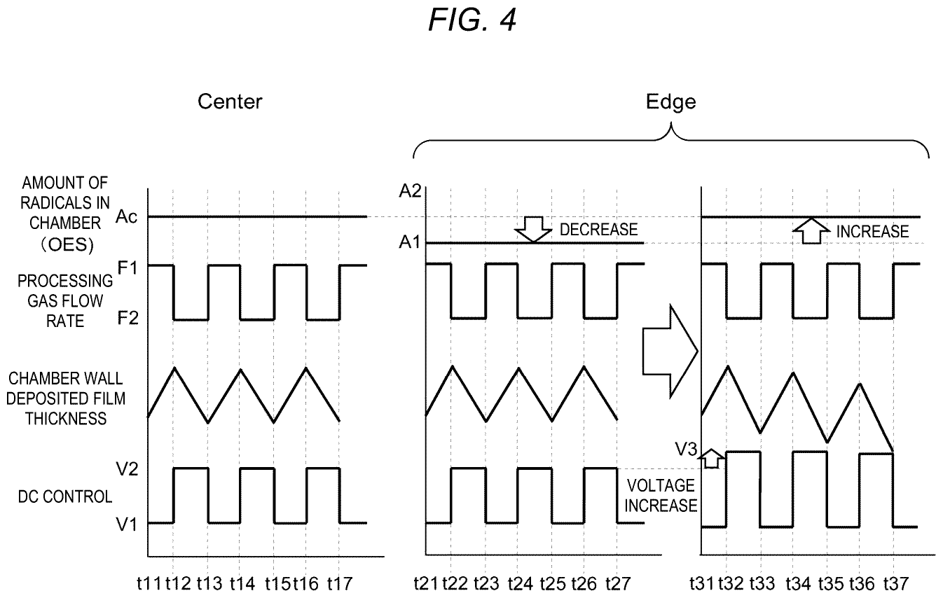

FIG. 4 is a timing chart showing an example of an operation of the plasma processing device 100 according to the first embodiment. A timing chart on a left side of FIG. 4 shows an example of an operation relating to a central portion (center) of the wafer W. A timing chart in a center and on a right side of FIG. 4 shows an example of an operation relating to an outer peripheral portion (edge) of the wafer W.

A horizontal axis of a graph in FIG. 4 indicates time. A vertical axis of a graph in FIG. 4 indicates an amount of radicals in the processing chamber 11 (in the plasma P) during a plasma processing of the wafer W, a flow rate of processing gas, a thickness of the deposited film D on an inner wall of the processing chamber 11, and a direct current voltage of a direct current (DC) control. In DC control of FIG. 4, for example, an increase in the vertical axis indicates an increase of the negative voltage. The amount of radicals in the processing chamber 11 indicates a result of a detection by the sensor 16. The radicals are, for example, a fluorocarbon-based or carbon-based active species. The flow rate of processing gas indicates a flow rate of processing gas supplied by the processing gas supply unit 15. The thickness of the deposited film D on the inner wall of the processing chamber 11 shows an example of a change over time in the thickness of the deposited film D. The direct current voltage of the DC control indicates a voltage applied by the direct current power supply 17.

Firstly, an operation relating to a central portion of the wafer W will be described.

Firstly, at a time t11, the control unit 19 adjusts the flow rate of processing gas to a flow rate F1. Also, the control unit 19 adjusts the voltage applied (the DC control) by the upper direct current power supply 171C to a voltage V1. The voltage V1 is, for example, 0V.

In a period from the time t11 to a time t12, reaction products generated by a plasma processing are deposited in the processing chamber 11, because of which the thickness of the deposited film D continually increases.

Next, at the time t12, the control unit 19 adjusts the voltage applied by the upper direct current power supply 171C from the voltage V1 to a voltage V2. The voltage V2 is a voltage that is lower than the voltage V1. That is, the control unit 19 causes the upper direct current power supply 171C to apply a negative voltage. Also, the control unit 19 adjusts the flow rate of processing gas from the flow rate F1 to a flow rate F2. The flow rate F2 is a flow rate that is lower than the flow rate F1. That is, the control unit 19 causes the flow rate of processing gas to decrease.

In a period from the time t12 to a time t13, the deposited film D is etched by an application of direct current voltage, because of which the thickness of the deposited film D continually decreases. Radicals are supplied into the processing chamber 11 (into the plasma P) from the deposited film D owing to the application of direct current voltage.

Also, the amount of radicals in the processing chamber 11 is approximately constant (a predetermined value Ac) during the period from the time t11 to the time t12 and the period from the time t12 to the time t13. This is because the flow rate of processing gas is reduced in such a way as to restrict an increase in the amount of radicals caused by an application of direct current voltage. That is, the control unit 19 controls the processing gas supply unit 15 in such a way as to cause the amount of processing gas supplied to decrease during an application of direct current voltage by the multiple of direct current power supplies 17.

Next, at the time t13, the control unit 19 returns the voltage applied by the upper direct current power supply 171C from the voltage V2 to the voltage V1. That is, the control unit 19 causes the application of voltage by the upper direct current power supply 171C to stop. Also, the control unit 19 returns the flow rate of processing gas from the flow rate F2 to the flow rate F1.

Subsequently, a control the same as that for the period from the time t11 to the time t13 is executed repeatedly. That is, the control unit 19 controls the multiple of direct current power supplies 17 in such a way as to apply a direct current voltage in a predetermined cycle.

Next, an operation relating to an outer peripheral portion of the wafer W will be described.

In the example shown in FIG. 4, voltage applied by the upper direct current power supply 171E changes partway through the operation (during a period from a time t21 to a time t27 and a period from a time t31 to a time t37).

In the example shown in FIG. 4, a DC control with respect to the upper direct current power supply 171E shown in the period from the time t21 to the time t27 is approximately the same as a DC control with respect to the upper direct current power supply 171C shown in a period from the time t11 to a time t17. However, in some cases, the amount of radicals in the outer peripheral portion of the wafer W decreases to a predetermined value A1, which is lower than the predetermined value Ac of radicals in the central portion of the wafer W. This is because the environment in the processing chamber 11 is not necessarily the same between the central portion and the outer peripheral portion of the wafer W, with the plasma P not being uniform, or the like. As the amount of radicals differs between the central portion and the outer peripheral portion of the wafer W, there is a possibility of etching not being carried out uniformly, and in-plane uniformity of the wafer W decreasing.

Therefore, the control unit 19 increases the direct current voltage that the upper direct current power supply 171E is caused to apply from the voltage V2 to a voltage V3. When a result of a detection by the sensor 16 is the predetermined value A1 or lower, the control unit 19 controls the direct current power supply 17 in a corresponding position in such a way as to raise the direct current voltage applied. Meanwhile, when a result of a detection by the sensor 16 is a predetermined value A2 or greater, the control unit 19 controls the direct current power supply 17 in a corresponding position in such a way as to lower the direct current voltage applied. The predetermined value A2 is higher than the predetermined value A1.

In the period from the time t31 to the time t37, the amount by which the deposited film D decreases increases because of the direct current voltage applied rising. The deposited film D is etched owing to an application of direct current voltage, because of which the amount of radicals supplied to the plasma P from the deposited film D increases owing to the direct current voltage applied rising. Because of this, in the example shown in FIG. 4, the amount of radicals in the period from the time t31 to the time t37 rises from the predetermined value A1 to the predetermined value Ac. That is, the amount of radicals can be adjusted to be approximately the same between the central portion of the wafer W and the outer peripheral portion.

Also, as shown in FIG. 4, the flow rate of processing gas is not caused to change between the period from the time t21 to the time t27 and the period from the time t31 to the time t37. When the flow rate of processing gas is increased in order to increase the amount of radicals in the outer peripheral portion of the wafer W, the central portion of the wafer W is also affected, and the amount of radicals increases. As opposed to this, the amount of radicals in the outer peripheral portion of the wafer W can be locally increased, without affecting the central portion of the wafer W, by changing the voltage that the upper direct current power supply 171E is caused to apply. That is, the control unit 19 controls the processing gas supply unit 15 in such a way that the amount of processing gas supplied is approximately the same in response to a result of a detection by the sensor 16.

Regarding in-plane uniformity, for example, when an abnormality occurs in a form of a hole formed by etching on the outer peripheral portion side, the voltage applied on the outer peripheral portion side may be changed. By so doing, in-plane uniformity can be improved.

Also, in the example shown in FIG. 4, DC control of the direct current power supply 17 is carried out in such a way that the amount of radicals is approximately the same between the central portion of the wafer W and the outer peripheral portion. However, the amount of radicals need not necessarily be adjusted in such a way as to be the same. In this case, for example, the predetermined value A1 and the predetermined value A2 may differ between the upper direct current power supply 171C and the upper direct current power supply 171E.

Also, in some cases, an etch selectivity can be changed in accordance with the amount of radicals supplied from the deposited film D. In-plane uniformity can also be improved by adjusting selectivity.

According to the first embodiment, as heretofore described, the control unit 19 controls the multiple of direct current power supplies 17 in such a way that the direct current power supplies 17 apply a direct current voltage independently of each other. Owing to the application of direct current voltage, the deposited film D in the processing chamber 11 can be partially removed, and the cleaning time can be shortened. Also, the multiple of direct current power supplies 17 can be controlled individually, because of which the in-plane uniformity of the wafer W can be improved.

Also, by causing the multiple of direct current power supplies 17 to apply direct current voltage during a plasma processing (during etching of a processing target film of the wafer W), the control unit 19 etches the deposited film D accumulated in the processing chamber 11, and supplies radicals to the inside of the processing chamber 11 from the deposited film D in such a way that the radicals can be utilized in the plasma processing (the etching of the processing target film of the wafer W). Because of this, etching of the deposited film D can be utilized in a supply of radicals to the plasma P, while shortening the cleaning time. An etching of the deposited film D owing to an application of direct current voltage may also be, for example, a sputtering.

Also, as shown in FIG. 4, the flow rate of processing gas can be lowered during an application of direct current voltage. Because of this, an amount of processing gas used can be restricted.

The number and arrangement of the multiple of direct current power supplies 17 are not limited to the examples shown in FIGS. 2 and 3.

Also, in the example shown in FIG. 4, times for which the voltages V1 and V2 are applied are approximately the same between the upper direct current power supply 171C and the upper direct current power supply 171E, while a magnitude of direct current voltage is changed. Not being limited to this, however, for example, the times for which the voltages V1 and V2 are applied may be changed instead of the direct current voltage. When a result of a detection by the sensor 16 is the predetermined value A1 or lower, the control unit 19 controls the direct current power supply 17 in a corresponding position in such a way as to raise a ratio of the time for which the voltage V2 is applied with respect to the time for which the voltage V1 is applied. Meanwhile, when a result of a detection by the sensor 16 is the predetermined value A2 or greater, the control unit 19 controls the direct current power supply 17 in a corresponding position in such a way as to lower a ratio of the time for which the voltage V2 is applied with respect to the time for which the voltage V1 is applied.

### Comparative Example

A case wherein the direct current power supply 17 is not provided will be described as a comparative example.

A plasma processing device according to the comparative example carries out an operation the same as that in the period from the time t11 to the time t12 in FIG. 4. That is, the deposited film D continues to accumulate in the processing chamber 11 while a plasma processing is continued.

Herein, in some cases, an ease with which the deposited film D accumulates in the processing chamber 11, and a quality of the deposited film D, differ in accordance with a kind of gas used in a gas processing. For example, a low temperature etching is carried out at a temperature of, for example, 0° C. or less. A low temperature etching is such that the kind of processing gas differs in comparison with, for example, a room temperature etching carried out at a room temperature higher than 0° C. A processing gas used in a low temperature etching is such that, for example, in comparison with a case of a room temperature gas, an amount of oxygen (O₂) is small, and a large amount of hydrogen (H₂) is included. Depending on a difference in the types of gas in the processing gas, for example, the deposited film D is more easily formed, or the deposited film D is of a quality that is difficult to clean. As a result of this, a low temperature etching is such that there is a possibility of a cleaning time becoming longer still than in the case of a room temperature etching. Also, it is difficult to minutely restrict a polarization in a spatial distribution of the amount of radicals in the processing chamber 11 (in the plasma P). In this case, there is a possibility of the in-plane uniformity of the wafer W decreasing.

In response to this, in the first embodiment, the control unit 19 controls the multiple of direct current power supplies 17 in such a way that the direct current power supplies 17 apply a direct current voltage independently of each other. Because of this, the deposited film D in the processing chamber 11 is partially removed during a plasma processing (during an etching of a processing target film of the wafer W), and a subsequent cleaning time can be shortened. Also, the multiple of upper direct current power supplies 171C, 171M, and 171E and the multiple of side wall direct current power supplies 172U and 172L can be controlled individually. Because of this, the in-plane uniformity of the wafer W can be improved by adjusting the spatial distribution of the amount of radicals in the processing chamber 11 (in the plasma P).

### Second Embodiment

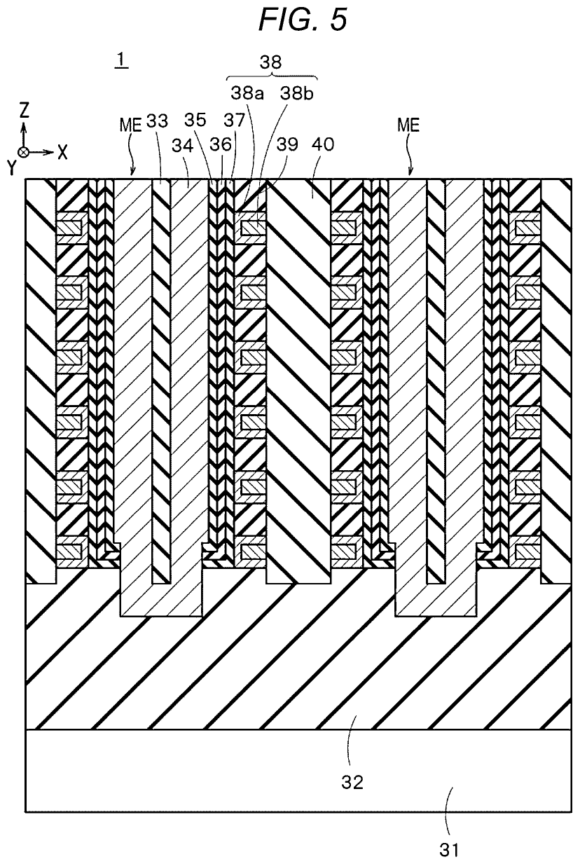

FIG. 5 is a sectional view showing an example of a structure of a semiconductor device according to a second embodiment. The semiconductor device of FIG. 5 includes a flash memory of a three-dimensional structure, and is manufactured from the wafer W of the first embodiment. FIG. 5 shows two memory elements ME in the flash memory.

The semiconductor device of FIG. 5 includes a semiconductor substrate 31 and an underlayer film 32. The underlayer film 32 includes a conductive layer or a semiconductor layer in an insulating layer such as a silicon oxide film, and these may have a stacked structure. Alternatively, the underlayer film 32 need not be provided. The semiconductor device of FIG. 5 further includes a first memory insulating film 33, a semiconductor layer 34, a second memory insulating film 35, a charge storage layer 36, a third memory insulating film 37, a multiple of conductive layers 38, and a multiple of insulating films 39. The semiconductor device of FIG. 5 further includes an insulating film 40.

An example of the semiconductor substrate 31 is a silicon substrate. The underlayer film 32 may be formed directly on the semiconductor substrate 31, or may be formed across another layer on the semiconductor substrate 31.

The first memory insulating film 33 has a columnar form that extends in the Z direction. An example of the first memory insulating film 33 is a silicon oxide film.

The semiconductor layer 34 is in contact with a side face of the first memory insulating film 33. The semiconductor layer 34 has a tubular form that extends in the Z direction in a periphery of the first memory insulating film 33, excepting a portion in a vicinity of a bottom face of the first memory insulating film 33. An example of the semiconductor layer 34 is a polysilicon layer.

The second memory insulating film 35 is in contact with a side face of the semiconductor layer 34. The second memory insulating film 35 has a tubular form that extends in the Z direction in a periphery of the semiconductor layer 34. An example of the second memory insulating film 35 is a silicon oxide film.

The charge storage layer 36 is in contact with a side face of the second memory insulating film 35. The charge storage layer 36 has a tubular form that extends in the Z direction in a periphery of the second memory insulating film 35. An example of the charge storage layer 36 is a silicon nitride film.

The third memory insulating film 37 is in contact with a side face of the charge storage layer 36. The third memory insulating film 37 has a tubular form that extends in the Z direction in a periphery of the charge storage layer 36. An example of the third memory insulating film 37 is a silicon oxynitride film.

The multiple of conductive layers 38 and the multiple of insulating films 39 are stacked alternately on the underlayer film 32, and are in contact with a side face of the third memory insulating film 37. The conductive layers 38 and the insulating films 39 enclose the third memory insulating film 37. Each conductive layer 38 includes a barrier metal layer 38a and a wiring member layer 38b. Examples of the barrier metal layer 38a are a titanium nitride (TiN) layer, a tantalum nitride (TaN) layer, a tungsten nitride (WN) layer, and the like. Examples of the wiring member layer 38b are a nickel (Ni) layer, a cobalt (Co) layer, a tungsten (W) layer, and the like. An example of each insulating film 39 is a silicon oxide film.

The insulating film 40 divides the multiple of conductive layers 38 in the Y direction. An example of the insulating film 40 is a silicon oxide film.

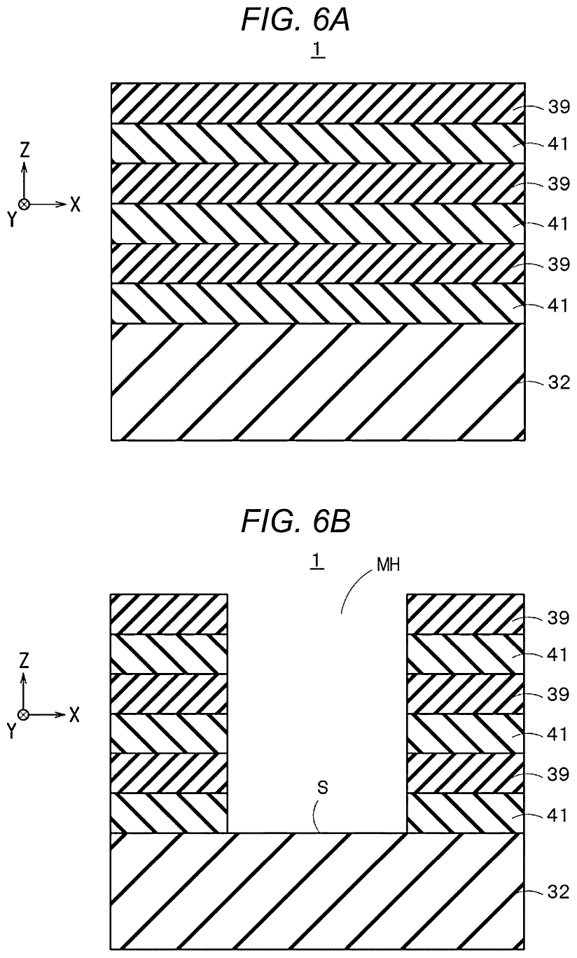

FIGS. 6A to 10B are sectional views showing an example of a method of manufacturing the semiconductor device according to the second embodiment.

Firstly, the underlayer film 32 is formed on the semiconductor substrate 31, which is not shown, and a multiple of sacrificial films 41 and the multiple of insulating films 39 are formed alternately on the underlayer film 32 (FIG. 6A). An example of each sacrificial film 41 is a silicon nitride film. An example of each insulating film 39 is a silicon oxide film.

Next, a memory hole MH that penetrates the sacrificial film 41 and the insulating film 39 to reach the underlayer film 32 is formed using lithography and plasma etching (FIG. 6B). Reference sign S indicates a bottom face of the memory hole MH. The plasma etching is carried out in the plasma processing device 100 according to the first embodiment using the plasma processing method of the first embodiment. Although a multiple of the memory holes MH are formed in the present process, FIG. 6B shows one memory hole MH among the multiple of memory holes MH.

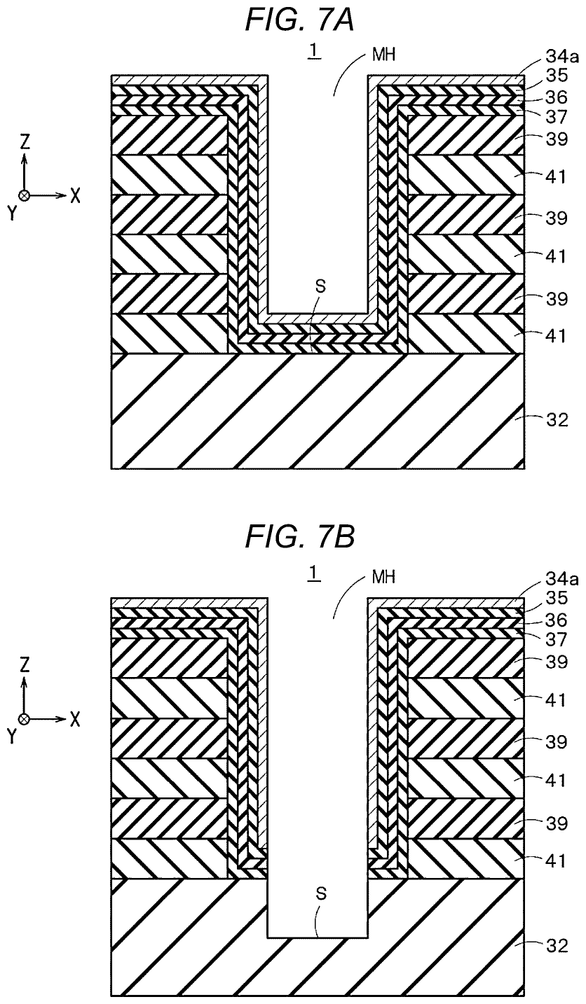

Next, the third memory insulating film 37, the charge storage layer 36, the second memory insulating film 35, and a first layer 34a of the semiconductor layer 34 are formed sequentially over a whole face of the semiconductor substrate 31 (FIG. 7A). As a result of this, the third memory insulating film 37, the charge storage layer 36, the second memory insulating film 35, and the first layer 34a are formed sequentially on a side face and the bottom face S of the memory hole MH. An example of the first layer 34a is an amorphous silicon layer.

Next, the third memory insulating film 37, the charge storage layer 36, the second memory insulating film 35, and the first layer 34a are removed from the bottom face S of the memory hole MH using lithography and etching (FIG. 7B). As a result of this, the bottom face S of the memory hole MH is exposed again. Furthermore, owing to the underlayer film 32 also being etched, the bottom face S of the memory hole MH becomes lower than an uppermost face of the underlayer film 32. This etching may be carried out in the plasma processing device 100 according to the first embodiment.

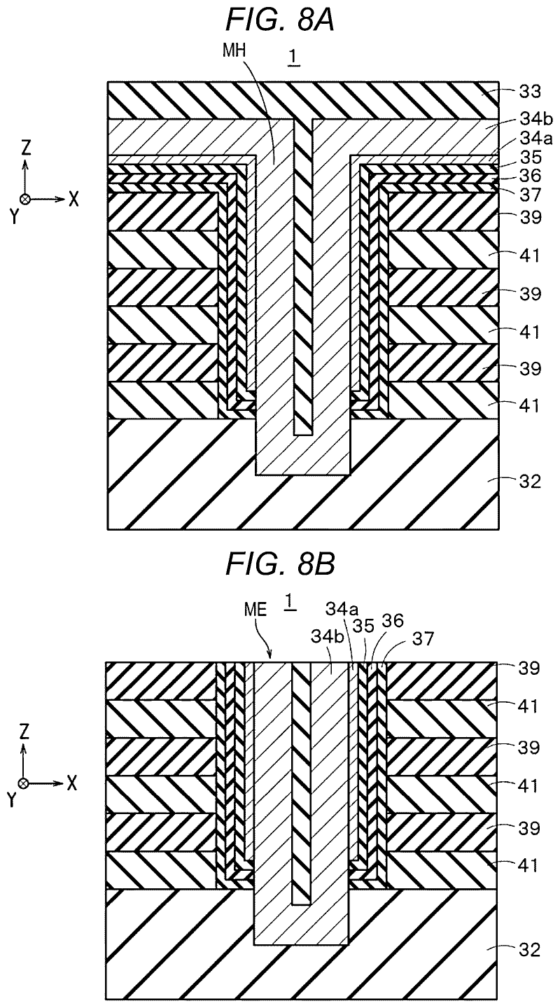

Next, a second layer 34b of the semiconductor layer 34 and the first memory insulating film 33 are formed sequentially over the whole face of the semiconductor substrate 31 (FIG. 8A). As a result of this, the second layer 34b is formed on the bottom face S of the memory hole MH, and the second layer 34b is formed across the third memory insulating film 37, the charge storage layer 36, the second memory insulating film 35, and the first layer 34a on the side face of the memory hole MH. Furthermore, the memory hole MH is completely filled with the first memory insulating film 33. An example of the second layer 34b is an amorphous silicon layer.

Next, surfaces of the first memory insulating film 33 and the semiconductor layer 34 are planarized using chemical mechanical polishing (CMP) (FIG. 8B). Subsequently, the semiconductor layer 34 is crystallized by the semiconductor substrate 31 being annealed, changing to a monocrystalline silicon layer.

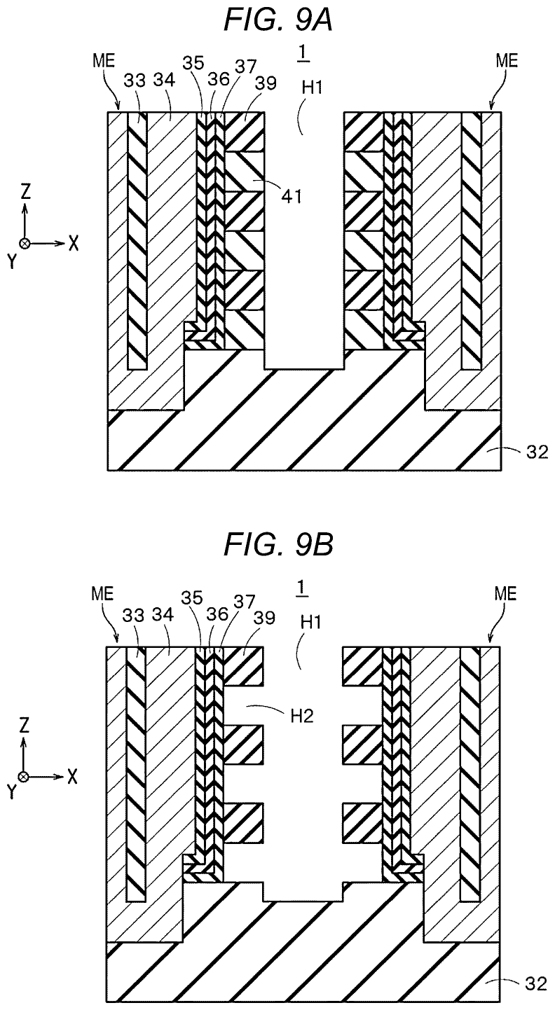

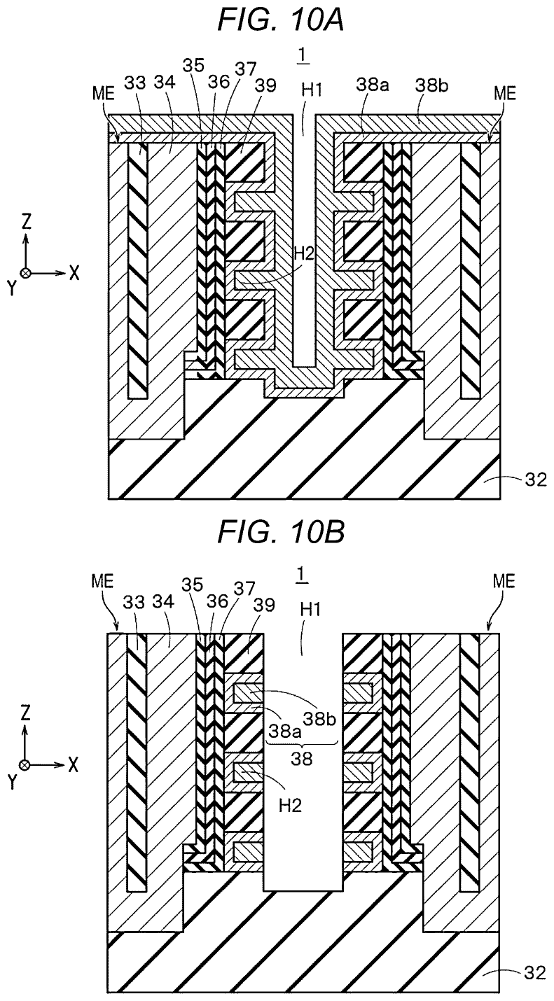

While FIGS. 6A to 8B show a cross-section of one memory element ME, FIGS. 9A to 10B show cross-sections of two memory elements ME.

Next, an aperture portion H1 that penetrates the sacrificial film 41 and the insulating film 39 to reach the underlayer film 32 is formed using lithography and plasma etching (FIG. 9A). In this process, a bottom face of the aperture portion H1 becomes lower than the uppermost face of the underlayer film 32 owing to the underlayer film 32 also being etched. The plasma etching is carried out in the plasma processing device 100 according to the first embodiment. The aperture portion H1 is formed in a region in which the insulating film 40 of FIG. 5 is to be formed.

Next, using a selective etching, the sacrificial film 41 is removed while causing the insulating film 39 to remain (FIG. 9B). As a result of this, a multiple of recessed portions H2 are formed among the insulating films 39. The recessed portion H2 is also formed between the insulating film 39 in a bottommost layer and the underlayer film 32. Owing to this etching, a side face of the third memory insulating film 37 is exposed in the recessed portions H2.

Next, the barrier metal layer 38a and the wiring member layer 38b are formed sequentially over the whole face of the semiconductor substrate 31 (FIG. 10A). As a result of this, the barrier metal layer 38a is formed on a top face, a bottom face, and a side face of each recessed portion H2, and the wiring member layer 38b is formed across the barrier metal layer 38a in each recessed portion H2. The present process is carried out in such a way that the recessed portion H2 is completely filled with the barrier metal layer 38a and the wiring member layer 38b.

Next, the barrier metal layer 38a and the wiring member layer 38b are etched using a wet etching (FIG. 10B). As a result of this, the barrier metal layer 38a and the wiring member layer 38b outside each recessed portion H2 are removed, and the conductive layer 38 including the barrier metal layer 38a and the wiring member layer 38b is formed in each recessed portion H2.

Subsequently, the insulating film 40 is formed in the aperture portion H1. Furthermore, various kinds of interlayer insulating film, wiring layer, plug layer, and the like are formed on the semiconductor substrate 31. In this way, the semiconductor device of the present embodiment is manufactured.

In the present embodiment, as heretofore described, a semiconductor device is manufactured from the wafer W by a plasma processing of the wafer W being executed using the plasma processing device according to the present embodiment. Therefore, according to the present embodiment, a cleaning time can be shortened.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing device, comprising:
a chamber;
a plurality of direct current power supplies provided in an upper portion and on a side wall of the chamber, wherein the direct current power supplies are configured to operate individually; and
a controller configured to control the direct current power supplies such that the direct current power supplies apply respective direct current voltages independent of each other.

2. The plasma processing device according to claim 1, wherein the direct current power supplies include
one or more upper direct current power supplies provided in differing positions in the upper portion of the chamber and each configured to apply a direct current voltage to the upper portion of the chamber, and
one or more side wall direct current power supplies provided in differing positions on the side wall of the chamber and each configured to apply a direct current voltage to the side wall of the chamber.

3. The plasma processing device according to claim 1, further comprising:
a gas supplier configured to supply a gas into the chamber; and
a gas processor including an electrode and configured to convert the gas into plasma, wherein
the controller is further configured to control the direct current power supplies causing the direct current power supplies to apply the independent direct current voltages during a plasma processing.

4. The plasma processing device according to claim 3, further comprising
a sensor configured to detect an amount of radicals in the chamber, wherein
the controller is further configured to control the direct current power supplies causing the direct current power supplies to apply the independent direct current voltages based on the detected amount of radicals.

5. The plasma processing device according to claim 4, wherein the controller is further configured to calculate a spatial distribution of the radicals in the chamber based on the detected amount of radicals, and control the direct current power supplies causing the direct current power supplies to apply the independent direct current voltages based on the calculated spatial distribution.

6. The plasma processing device according to claim 5, wherein
the controller is further configured to control each of the direct current power supplies to a corresponding position to raise the applied direct current voltage when a result of a detection by the sensor is equal to or lower than a first predetermined value, and control each of the direct current power supplies to a corresponding position to lower the applied direct current voltage when the result of the detection by the sensor is equal to greater than a second predetermined value, and
the second predetermined value is higher than the first predetermined value.

7. The plasma processing device according to claim 4, wherein
the controller is configured to control the gas supplier such that an amount of the gas supplied is approximately the same in response to a result of a detection by the sensor.

8. The plasma processing device according to claim 3, wherein
the controller is further configured to control the gas supplier in accordance with a timing of when the direct current voltages are applied.

9. The plasma processing device according to claim 8, wherein
the controller is further configured to control the gas supplier so as to reduce an amount of the gas supplied during applying the direct current voltages.

10. The plasma processing device according to claim 3, wherein
the controller is further configured to control the direct current power supplies so as to apply a direct current in a predetermined cycle.

11. The plasma processing device according to claim 3, wherein
the gas includes a fluorocarbon gas.

12. A plasma processing method using a plasma processing device that includes a chamber, a plurality of direct current power supplies provided in an upper portion and on a side wall of the chamber, and controlled individually, and a controller configured to control the direct current power supplies such that the direct current power supplies apply respective direct current voltages that are independent of each other, wherein
a deposited film accumulated in the chamber is etched by the direct current power supplies being caused to apply a direct current voltage during a plasma processing.

13. A semiconductor device manufacturing method whereby a processing target film formed on a wafer is etched using a plasma processing device that includes a chamber housing the wafer, a plurality of direct current power supplies provided in an upper portion and on a side wall of the chamber, and controlled individually, and a controller configured to control the direct current power supplies such that the direct current power supplies apply respective direct current voltages independent of each other, wherein
a deposited film accumulated in the chamber is etched by the multiple of direct current power supplies being caused to apply a direct current voltage during an etching of the processing target film.
